(19) United States
(12) Patent Application Publication
(10) Pub. No.: US 2001/0017506 A1
(43) Pub. Date: Aug. 30, 2001

(54) Piezoelectric transformer and assembly including such a transformer

(76) Inventors: Wilhelmus Gerardus Maria Ettes, Drachten (NL); Poul Erik De Haan, Drachten (NL)

Correspondence Address: Corporate Patent Counsel, U.S. Philips Corporation, 580 White Plains Road, Tarrytown, NY, 10591, US

(21) Appl. No.: 09/761,244

(22) Filed: Jan. 16, 2001

(30) Foreign Application Priority Data
Jan. 20, 2000 (EP) 00200222.8

(51) Int. Cl. H01L 41/04

(52) U.S. Cl. 310/359; 310/365; 310/366; 310/318

(57) ABSTRACT

A piezoelectric transformer has a body made of a piezoelectric material polarized in segments. The segments each have diametrically opposed polarization sides (23-28) transverse to the direction of polarization. A pair of input electrodes (13, 14) and a pair of output electrodes (15, 16) are disposed on a first and a second pair of diametrically opposed polarization sides of the body (19). At least one of the electrodes (14, 32, 33) extends beyond the polarization side (28) on which this electrode is disposed, in order to increase a capacitance between this input electrode and one or both output electrodes (15, 16) and thereby reduce common mode currents.

The invention relates to a piezoelectric transformer as defined in the introductory part of claim 1, and to an assembly including such a transformer.

Such a piezoelectric transformer is known from U.S. Pat. No. 2,830,274.

A piezoelectric transformer forms an electrical-mechanical-electrical coupled system. If a voltage having a frequency substantially equal to the resonant frequency of the body of a piezoelectric material is applied to the input electrodes, the body of a piezoelectric material is set into vibration. The deformations attendant upon said vibration in their turn result in a voltage being produced across the output electrodes. In principle, this voltage has a frequency equal to the frequency of vibration of the body of a piezoelectric material.

The relationship between the input voltage and current, on the one hand, and the output voltage and current, on the other hand, depends inter alia on the dimensions of the body and the segments, the choice of the piezoelectric material, the direction or directions of polarization and the load.

In order to limit switching losses it is advantageous to apply a voltage which varies as a function of time in accordance with a squarewave pattern of said frequency to the input electrodes. This means that dV/dt of the voltage across the input electrodes is comparatively large. Owing to the parasitic capacitance of the transformer, this results in currents in the secondary circuit. Since the secondary circuit, which is connected to the output electrodes, is capacitively coupled to its environment, or—in a test arrangement—to a reference plate which is also coupled to the primary circuit connected via the input electrodes, high-frequency currents are produced between the secondary circuit and the environment. These currents are referred to as common mode currents. These currents may disturb the operation of other equipment in the proximity. Therefore, standards have been laid down as regards the degree to which common mode currents are admissible.

It is possible to limit these currents by capacitively coupling the input side of the transformer to the secondary circuit at the output side of the transformer via a so-called Y capacitor. However, this restricts the miniaturization possibilities and has a cost-raising effect, particularly if the transformer serves as a SELV (Safe Extra Low Voltage) transformer for, for example, an electric shaver and should comply with safety requirements in accordance with IEC335-2-8. In such a case two series-connected Y capacitors are required. For a reduction of the common mode current by 40 dB the capacitance of the series-connected capacitors should be 100 times as high as the parasitic capacitance of the transformer.

It is an object of the invention to provide a solution which, when a piezoelectric transformer is used, enables common mode currents to be limited in a more efficient way requiring less volume, while a primary voltage with a large dV/dt is maintained.

According to the present invention this is achieved by means of a transformer as defined in claim 1.

Since at least one of the electrodes extends along said piezoelectric body beyond the polarization side on which it is disposed electrically, in order to increase a capacitance between one of the input electrodes and at least one of the output electrodes, the desired capacitive coupling between the primary circuit and the secondary circuit can be achieved by means of the piezoelectric transformer in accordance with the invention without the use of any separate capacitors. Thus, the desired capacitive coupling is integrated in the construction of the piezoelectric transformer.

The invention can also be embodied in an assembly as defined in claim 10. The transformer in accordance with the invention is particularly advantageous if, on the one hand, a certain minimum electrical isolation is required between the primary circuit and the secondary circuit for reasons of safety, as a result of which the electrical appliance itself may comply with less stringent electrical safety requirements but, on the other hand, mass production at very low costs and a compact construction are of very great importance.

Other particularly advantageous embodiment of the invention are defined in the dependent claims.

Further objects, constructional aspects, effects and details of the invention will be described hereinafter with reference to embodiments shown in the drawings by way of example. In the drawings:

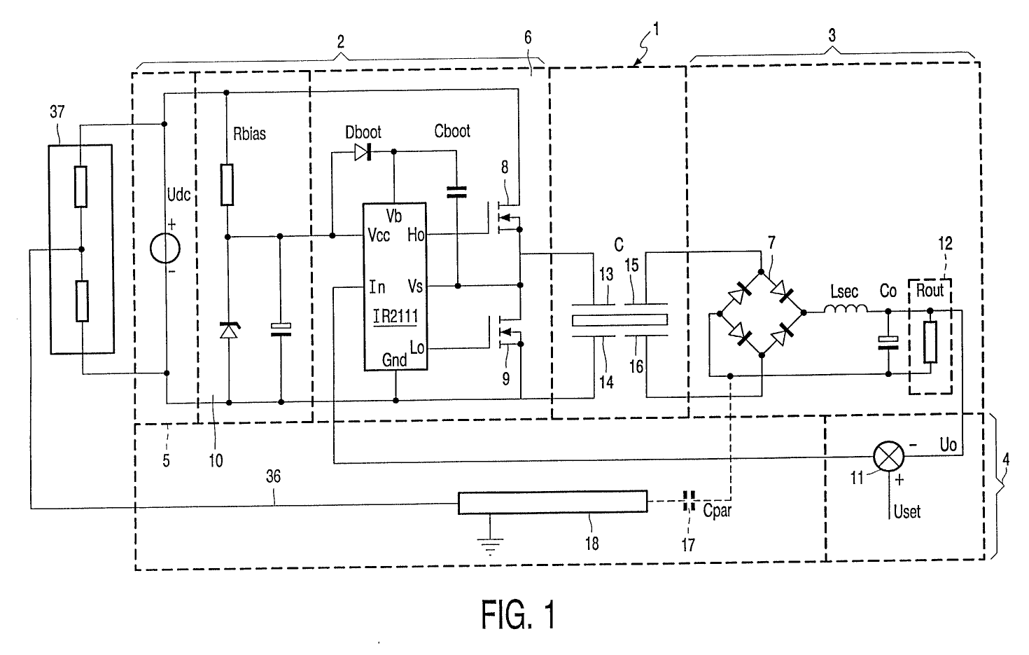

FIG. 1 shows an electrical circuit diagram of a piezoelectric transformer in accordance with the invention having a primary circuit and a secondary circuit,

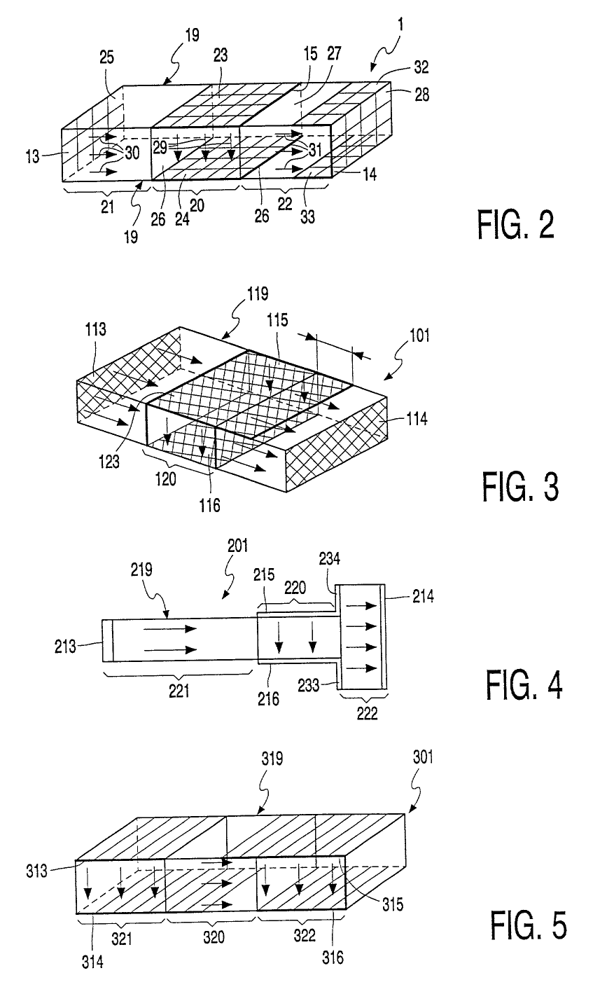

FIG. 2 is a diagrammatic perspective view which shows a first example of a piezoelectric transformer in accordance with the invention,

FIG. 3 is a diagrammatic perspective view which shows a second example of a piezoelectric transformer in accordance with the invention,

FIG. 4 is a diagrammatic side view which shows a third example of a piezoelectric transformer in accordance with the invention,

FIG. 5 is a diagrammatic perspective view which shows a fourth example of a piezoelectric transformer in accordance with the invention, and

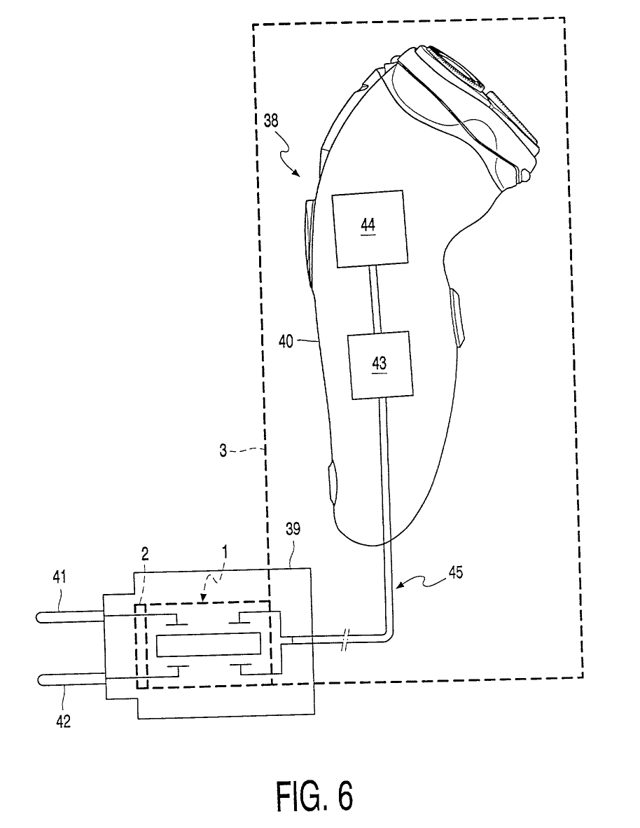

FIG. 6 diagrammatically shows an assembly in accordance with the invention.

FIG. 1 shows an electrical transformer 1 in accordance with the invention in an embodiment which also includes a primary circuit 2, a secondary circuit 3 and a control circuit 4.

A block 5 bearing the reference numeral 5 represents a structure for filtering and rectifying a mains voltage into a direct voltage U_{dc}.

A block 6 represents a power supply circuit with a half bridge converter for generating the voltage applied across the input electrodes 13, 14 of the transformer 1. This power supply circuit includes two FETs 8, 9 which are driven in turns by an IC in the form of a level shifter IR2111. Such a level shifter is commercially available, for example, from International Rectifier.

To power the level shifter IR2111 and the control devices 4 a tapped resistor R_{bias} has been provided.

The block 3 represents the secondary circuit, which is connected to the transformer 1 via the output electrodes 15, 16 thereof. The secondary circuit 3 in the present example has a bridge rectifier 7, a self-inductance L_{sec}, a capacitance Cₒ and, therein, a powered structure 12 having a resistance Rₒᵤₜ. The secondary circuit may extend, for example, from a so-called power plug (a plug having a housing which also accommodates a transformer), via a low-voltage supply lead, to an appliance to be powered, such as an electric shaver or a battery charger.

For comparing the output voltage Uₒ applied across the powered structure 12 with a reference voltage Uₛₑₜ a control structure has been provided, which in dependence on the detected deviation signals to the level shifter whether the frequency is to be increased or reduced. The minimum frequency with which the level shifter IR2111 is driven is preferably equal to the lowest possible resonant frequency of the piezoelectric transformer 1. The maximum frequency with which the level shifter IR2111 is driven is preferably limited in such a manner that subharmonic frequencies of the piezoelectric transformer 1 are not reached.

If, for example, the mains voltage increases, the direct voltage U_{dc} will increase and the voltage Uₒ produced in the secondary circuit will also increase. In response to this, the difference between the output voltage Uₒ and the desired voltage Uₛₑₜ increases. In its turn, this causes the frequency with which the level shifter IR2111 is driven to increase, as a result of which the output voltage Uₒ decreases again. Conversely, if the output voltage Uₒ is too low, the driving frequency with which the level shifter IR2111 is driven is reduced, as a result of which the output voltage Uₒ increases.

In order to limit switching losses it is advantageous to apply a voltage which varies as a function of time in accordance with a squarewave pattern to the input electrodes 13, 14. This means that dV/dt of the voltage across the input electrodes 13, 14 is comparatively large. Owing to the parasitic capacitance C of the transformer 1, this results in common mode currents between the input and output electrodes 13 and 15 and also between the input and output electrodes 13 and 16.

In the test arrangement shown the secondary circuit 3, which is connected to the output electrodes, is capacitively coupled to a reference plate 18, as is indicated by the capacitor 17 and the coupling including this capacitor, which are shown in broken lines. The primary circuit 2, which is connected via the input electrodes 13, 14, is also coupled to the reference plate 18. This coupling is formed by a physical conductor 36 coupled to a dummy mains 37, which is coupled to the primary circuit 2 for powering the transformer 1. It is obvious that, in practice, there is not such a reference plate 18 but the capacitive coupling takes the form of a coupling to current sinking capacitances in the environment. The described capacitive coupling between the secondary circuit and the environment also gives rise to common mode currents between the secondary circuit and the environment in the case of large dV/dt values in the primary circuit.

Since the electrodes 13-16 of the piezoelectric transformer 1 are constructed in such a manner that the capacitance between one of the input electrodes 14 and at least one of the output electrodes 15, 16 is substantially higher than the parasitic capacitance of the transformer between the other one of the input electrodes 13 and the output electrodes 15, 16, a capacitive coupling is obtained between the primary circuit 2 and the secondary circuit 3, as a result of which the common mode current through the secondary circuit is reduced. The desired difference in capacitive coupling is thus integrated in the construction of the piezoelectric transformer. In the present example the capacitance between one of the input electrodes 14 and one of the output electrodes 16 is chosen to be 100 times as high as the parasitic capacitance of the transformer 1 for a 40 dB reduction of the common mode current in the mains lead. Preferably, the capacitance between one of the input electrodes and at least one of the output electrodes is chosen to be at least 2-10 times as high as the parasitic capacitance of the transformer 1 between the other ones of the input electrodes 13 and the output electrodes 15, 16.

FIG. 2 shows a first example of a transformer 1. The piezoelectric transformer 1 has a body 19 of a piezoelectric material. This body 19 together with the electrodes applied to it has a resonant frequency which dictates the resonant frequency of the piezoelectric transformer 1. The body 19 of a piezoelectric material is divided into a central segment 20 and two outer segments 21, 22 at opposite sides of the central segment 20.

The piezoelectric material in the central segment 20 is polarized in a direction transverse to the longitudinal direction of the body 19 of a piezoelectric material, as is indicated by arrows 29. The piezoelectric material in the outer segments 21, 22 is polarized in the longitudinal direction of the body 19 of a piezoelectric material, as is indicated by arrows 30, 31.

The segments 20-21 each have diametrically opposed polarization sides 23, 24, 25, 26, 27, 28 transverse to the direction of polarization of the respective segment 20-21.

The input electrodes 13, 14 are arranged on a first pair 25, 28 of diametrically opposed polarization sides 23-28 of the body 19 of a piezoelectric material.

The output electrodes 15, 16 are arranged on a second pair of diametrically opposed polarization sides 23-28 of the body 19 of a piezoelectric material.

One of the input electrodes 14 extends into the parts 32, 33 beyond the polarization side 28 on which it is disposed along the piezoelectric body 19, as a result of which the capacitance between this input electrode 14 and the output electrodes 15, 16 is increased.

Thus, a capacitive coupling between the primary circuit 2 and the secondary circuit 3, by means of which common mode currents are reduced, can be obtained in an efficient manner requiring a very small volume.

If, for example, the segments 20-22 have a length of 12 mm and the parts 32, 33 of the electrode 14 which extend in the longitudinal direction of the body 19 beyond the polarization side 28 carrying the electrode 14 have a size of 4 mm, a minimum creeping distance of 8 mm is left between the primary electrodes 13, 14 and the secondary electrodes 15, 16. This is in compliance with the requirement of a minimum creeping distance of 6-8 mm imposed on SELV (Safe Extra Low Voltage) transformers.

All the segments may be polarized in the longitudinal direction of the body of a piezoelectric material, two of the electrodes being interposed between the central segment and one of the outer segments. This is known per se from U.S. Pat. No. 2,830,274. However, in the example shown in FIG. 2 the central segment 20 is polarized in a direction 29 transverse to the direction 30, 31 in which the outer segments 21, 22 are polarized. As a result of this, the electrodes 13-16 have to be provided only on outer surfaces of the body 19, which enables the transformer 1 to be manufactured efficiently. It is to be noted that in each of the transformers 101, 201 and 301 as shown in FIGS. 3-5 the central segment is polarized in a direction transverse to the direction in which the outer segments are polarized.

Furthermore, in the transformer shown in FIG. 2 the central segment 20 is polarized in a direction transverse to the longitudinal direction of the body 19 and a pair 13, 14 of the input and output electrodes is arranged on end faces 25, 28 of the body 19. The other ones 15, 16 of the electrodes are arranged on diametrically opposed outer surfaces of the central segment 20. Owing to these measures the capacitance between one of the input electrodes 14 and the output electrodes 15, 16 can be increased substantially in the case of segments 22 having a length which is comparatively large with respect to the thickness. The minimum creeping distance between the input electrodes 13, 14 and the output electrodes 15, 16 can then be larger than prescribed by the safety requirements for SELV equipment. This minimum creeping distance is preferably at least 6-8 mm.

For an effective and space-saving increase of the capacitance between one of the input electrodes 14 and the output electrodes 15, 16 it is also advantageous that one of the input electrodes 14 extends from the polarization side 28 on which it is disposed to the output electrodes 15, 16 along an outer surface of the body 19 of a piezoelectric material, which outer surface is oriented transversely to said side.

FIG. 3 shows an alternative embodiment. This transformer 101 has input electrodes 113, 114 and output electrodes 115, 116. The polarization of the segments of the body 119 of a piezoelectric material is similar to that of the example shown in FIG. 2. However, inn the present example one of the output electrodes 115 is prolonged in a direction towards the input electrode 114 beyond the polarization side 123 of the segment 120 on which it is disposed. It is also possible to prolong both output electrodes 115, 116 in a direction towards the input electrode 114.

FIG. 4 shows a transformer 201 having electrodes 213-216, one of the outer segments 222 being enlarged with respect to the other segments 220, 221 in a direction transverse to the longitudinal direction of the body 219 of a piezoelectric material. One of the input electrodes 214 has been enlarged accordingly and the output electrodes 215, 216 have upright flanges 233, 234 which extend along the outer segment 222, which has been enlarged in the height direction, without being in electrical contact therewith. The facing enlarged surfaces of the electrodes 214 and 215, 216 with the interposed piezoelectric material (which has a high dielectric constant) provide a particularly effective increase of the capacitance between one of the input electrodes 214 and the output electrodes 215, 216. It is to be noted that it is alternatively possible to provide only one of the two output electrodes with an upright flange opposite one of the input electrodes.

FIG. 5 shows a transformer 301 having electrodes 313-316 and a body 319 made up of segments 320-322. In the transformer in accordance with the present example the central segment 320 is polarized in the longitudinal direction of the body 319 of a piezoelectric material. The input electrodes 313, 314 are arranged on one of the outer segments 321 and the output electrodes 315, 316 are arranged on a second one of the outer segments 322. One of the input electrodes 314 and one of the output electrodes 315 extend along the central segment beyond the polarization side of the segment 321, 322 on which they are disposed. As a result of this, the capacitance between this input electrode 314 and this output electrode 315 is increased.

From the foregoing it will be evident to one skilled in the art that many other variants are conceivable within the scope of the invention. Thus, it is possible, for example, to extend both one of the input electrodes and two of the output electrodes in directions towards one another beyond the polarization sides of the segments on which these electrodes are disposed.

FIG. 6 shows an assembly including an electrical domestic appliance 38, in the present example a shaver, and a transformer 1 as described hereinbefore. The transformer together with a rectifier, not shown, in the secondary circuit is accommodated in a transformer housing 39 which is separate from a housing 40 of the appliance 38. The appliance 38 is included in a secondary circuit 3 which, in the transformer housing 39, is electrically isolated from a primary circuit 2 adapted to be coupled to the electric mains by means of contact pins 41, 42. The shaver 38 includes a converter 43, which converts the output voltage of the transformer 1 and the rectifier into a low supply voltage for the motor 44 of the shaver 38. The non-direct conversion of the voltage to the substantially lower voltage at which the motor operates has the advantage that it is not necessary to have correspondingly large current intensities through the comparatively long connecting lead 45.

The use of the transformer 1 illustrated in FIG. 6 is particularly advantageous because, on the one hand, a certain minimum electrical isolation between the primary and the secondary is required for safety reasons, as a result of which the shaver itself may comply with less stringent electrical safety requirements but, on the other hand, mass production at very low costs and a compact construction are of very great importance. Moreover, for such uses the lead 45 has a substantial capacitive coupling with the environment owing to its length, as a result of which the likelihood of disturbances caused by common mode currents increases.

1. A piezoelectric transformer, comprising:
a body (19; 119; 219; 319) of a piezoelectric material, which body (19; 119; 219; 319) has a resonant frequency, is divided into a central segment (20; 120; 220; 320) and two outer segments (21, 22; 121, 122; 221, 222; 321, 322) at opposite sides of said central segment (20; 120; 220; 320), in which segments the piezoelectric material is polarized in at least one direction of polarization (29, 30, 31), which segments each have diametrically opposed polarization sides (23-28; 123) transverse to the direction of polarization (29, 30, 31) of that segment;
a pair of input electrodes (13, 14; 113, 114; 213, 214; 313, 314) disposed on a first pair of said polarization sides (23-28; 123) of said body (19; 119; 219; 319), which sides are diametrically opposed with respect to one another; and
a pair of output electrodes (15, 16; 115, 116; 215, 216; 315, 316) disposed on a second pair of said polarization sides (23-28; 123) of said body (19; 119; 219; 319), which sides are diametrically opposed with respect to one another;
characterized in that at least one of said electrodes (14; 115; 214, 215, 216; 315) extends along said body (19; 119; 219; 319) of a piezoelectric material beyond the polarization side (28; 123) on which it is disposed, in order to increase a capacitance between one of the input electrodes (14; 114; 214; 314) and at least one of the output electrodes (15, 16; 115; 215, 216; 315).

2. A transformer as claimed in claim 1, in which the central segment (20; 120; 220; 320) is polarized in a first direction and said outer segments (21, 22; 121, 122; 221, 222; 321, 322) are polarized in a second direction transverse to said first direction, and in which said electrodes are disposed exclusively on outer surfaces of said body (19; 119; 219; 319).

3. A transformer as claimed in claim 2, in which said central segment (20; 120; 220) is polarized in a direction transverse to said longitudinal direction, in which the input or output electrodes (13, 14; 113; 114; 214, 215) are disposed on end faces of said body (19; 119; 219), and in which the other ones of said electrodes (15, 16; 115, 116; 215, 216) are disposed on diametrically opposed outer surfaces of said central segment (20; 120; 220).

4. A transformer as claimed in claim 3, in which one of said input electrodes (14) also extends from one of said polarization sides (28) towards at least one of said output electrodes (15, 16) along at least one outer surface of said body (19), which outer surface is oriented transversely to said one of said polarization sides.

5. A transformer as claimed in claim 2, in which said central segment (320) is polarized in said longitudinal direction, in which said input electrodes (313, 314) are disposed on a first one of said outer segments (321, 322), and in which said output electrodes (315, 316) are disposed on a second one of said outer segments (321, 322).

6. A transformer as claimed in claim 5, in which one of said input electrodes (314) also extends from one of said polarization sides towards at least one of said output electrodes (316) along an outer surface of said central segment (320).

7. A transformer as claimed in claim 1, 2, 3, 4, 5, or 6, further comprising a primary circuit (2) for generating a voltage of a frequency substantially equal to said resonant frequency, which primary circuit (2) is coupled to said piezoelectric body (19) via said input electrodes (13, 14).

8. A transformer as claimed in claim 1, 2, 3, 4, 5, 6, or 7, in which said input electrodes (13, 14; 113, 114; 213, 214; 313, 314) are disposed at a creeping distance of at least 6-8 mm from said output electrodes (15, 16; 115, 116; 215, 216; 315, 316).

9. A transformer as claimed in claim 1, 2, 3, 4, 5, 6, 7, or 8, in which the transformer has a parasitic capacitance and in which the capacitance between one of the input electrodes (14; 114; 214; 314) and at least one of the output electrodes (15, 16; 115, 116; 215, 216; 315, 316) is at least 2 times as high as the parasitic capacitance of the transformer (1; 101; 201; 301) between the other one of the input electrodes (13; 113; 213; 313) and at least one of the output electrodes ((15, 16; 115, 116; 215, 216; 315, 316).

10. An assembly including an electrical domestic appliance (38), such as a shaver, a battery charger or a depilator, and a transformer (1) as claimed in any one of the preceding claims, in which the transformer (1) is accommodated in a transformer housing (39) which is separate from a housing (40) of said appliance (38), and in which said appliance is included in a secondary circuit which, in said transformer housing, is electrically isolated from a primary circuit adapted to be coupled to the electric mains.

11. An assembly as claimed in claim 10, further including a power supply lead (45) between the transformer housing (39) and said appliance (38).
